(19) United States
(12) Patent Application Publication
(10) Pub. No.: US 2024/0363497 A1
(43) Pub. Date: Oct. 31, 2024

(54) SEMICONDUCTOR MODULE ARRANGEMENTS

(71) Applicant: Infineon Technologies AG, Neubiberg (DE)

(72) Inventors: Andressa COLVERO SCHITTLER, Ense (DE); Christian MÜLLER, Schweinfurt (DE)

(21) Appl. No.: 18/641,849

(22) Filed: Apr. 22, 2024

(30) Foreign Application Priority Data
Apr. 26, 2023 (DE) 102023110754.2

(51) Int. Cl. H01L 23/495; H01L 23/00; H01L 25/065

(52) U.S. Cl. CPC H01L 23/49506; H01L 23/49575; H01L 24/08; H01L 24/48; H01L 25/0652; H01L 2224/08145; H01L 2224/08245; H01L 2224/48138; H01L 2224/48155; H01L 2924/01013; H01L 2924/01029; H01L 2924/1306; H01L 2924/182

(57) ABSTRACT

A semiconductor module arrangement includes a substrate including a dielectric insulation layer and a first metallization layer arranged on a surface of the dielectric insulation layer, wherein the first metallization layer comprises a first section, a second section, and a third section, and a first semiconductor body and an identical second semiconductor body arranged on the first metallization layer, wherein each of the first semiconductor body and the second semiconductor body has a first contact pad, a second contact pad, and a third contact pad arranged on a top side of the respective semiconductor body that faces away from the substrate, wherein the third contact pad of the first semiconductor body is electrically coupled to the third section of the first metallization layer by means of a first electrical connection element, the third contact pad of the second semiconductor body is electrically coupled to the third section of the first metallization layer by means of a second electrical connection element, the semiconductor module arrangement further includes at least one third terminal element arranged on the third section, a first current path between the third contact pad of the first semiconductor body and the at least one third terminal element provides identical voltage and current transfer characteristics as a second current path between the third contact pad of the second semiconductor body and the at least one third terminal element, and each of the first and second electrical connection elements includes one or more bonding wires, one or more bonding ribbons, a connection rail, or a section of an additional metallization layer of the substrate that is contacted by corresponding vias.

### RELATED APPLICATION

This application claims priority to German Patent Application No. 102023110754.2, filed on Apr. 26, 2023, entitled “SEMICONDUCTOR MODULE ARRANGEMENTS”, which is incorporated by reference herein in its entirety.

### TECHNICAL FIELD

The instant disclosure relates to semiconductor module arrangements.

### BACKGROUND

Power semiconductor module arrangements often include at least one semiconductor substrate arranged in a housing. A semiconductor arrangement including a plurality of controllable semiconductor elements (e.g., IGBTs, MOSFETs, HEMTs, etc.) is arranged on each of the at least one substrate. Each substrate usually comprises a substrate layer (e.g., a ceramic layer), a first metallization layer deposited on a first side of the substrate layer, and, optionally, a second metallization layer deposited on a second side of the substrate layer. The controllable semiconductor elements are mounted, for example, on the first metallization layer. The second metallization layer may optionally be attached to a base plate. The layout of the semiconductor arrangement should be chosen to minimize the required size of the at least one substrate while, at the same time, preventing an unequal distribution of current densities, electrical losses, and thermal stress. Symmetry is often essential with respect to gate driving and parasitic inductances. Lateral semiconductor devices such as, e.g., GaN HEMTs, which have all contact pads (e.g., gate, source and drain contact pads) arranged on their top side and no contact pads on their bottom side, generally pose problems with regard to a symmetrical arrangement of the devices, especially for devices that are operated in parallel. Symmetrical arrangement of lateral devices often results in increased chip manufacturing costs, complex designs, and decreased flexibility in the production line.

Hence, there is a general need for a power semiconductor module comprising lateral semiconductor devices that overcomes the above-mentioned drawbacks.

### SUMMARY

A semiconductor module arrangement includes a substrate including a dielectric insulation layer and a first metallization layer arranged on a surface of the dielectric insulation layer, wherein the first metallization layer comprises a first section, a second section, and a third section, and a first semiconductor body and an identical second semiconductor body arranged on the first metallization layer, wherein each of the first semiconductor body and the second semiconductor body has a first contact pad, a second contact pad, and a third contact pad arranged on a top side of the respective semiconductor body that faces away from the substrate, wherein the third contact pad of the first semiconductor body is electrically coupled to the third section of the first metallization layer by means of a first electrical connection element, the third contact pad of the second semiconductor body is electrically coupled to the third section of the first metallization layer by means of a second electrical connection element, the semiconductor module arrangement further includes at least one third terminal element arranged on the third section, a first current path between the third contact pad of the first semiconductor body and the at least one third terminal element provides identical voltage and current transfer characteristics as a second current path between the third contact pad of the second semiconductor body and the at least one third terminal element, and each of the first and second electrical connection elements includes one or more bonding wires, one or more bonding ribbons, a connection rail, or a section of an additional metallization layer of the substrate that is contacted by corresponding vias.

Another semiconductor module arrangement includes a substrate including a dielectric insulation layer and a first metallization layer arranged on a surface of the dielectric insulation layer, wherein the first metallization layer comprises a first section, a second section, a third section, a fourth section, and a fifth section, wherein the second section horizontally surrounds each of the third section, the fourth section, and the fifth section, and identical first, second, third, and fourth semiconductor bodies arranged on the first metallization layer, wherein each of the first semiconductor body, the second semiconductor body, the third semiconductor body, and the fourth semiconductor body has a first contact pad, a second contact pad, and a third contact pad arranged on a top side of the respective semiconductor body that faces away from the substrate, wherein the third contact pad of the first semiconductor body is electrically coupled to the third section of the first metallization layer by means of a first electrical connection element, the third contact pad of the second semiconductor body is electrically coupled to the third section of the first metallization layer by means of a second electrical connection element, the third contact pad of the third semiconductor body is electrically coupled to the fourth section of the first metallization layer by means of a third electrical connection element, the third contact pad of the fourth semiconductor body is electrically coupled to the fourth section of the first metallization layer by means of a fourth electrical connection element, the fifth section is electrically coupled to the third section by means of an electrical connection element, the fifth section is electrically coupled to the fourth section by means of an electrical connection element, each of the electrical connection elements includes one or more bonding wires, one or more bonding ribbons, a connection rail, or a section of an additional metallization layer of the substrate that is contacted by corresponding vias, the power semiconductor module arrangement further includes at least one fifth terminal element arranged on the fifth section of the first metallization layer, and a current path between the at least one fifth terminal element and the third contact pad of the first semiconductor body provides identical voltage and current transfer characteristics as each of a current path between the at least one fifth terminal element and the third contact pad of the second semiconductor body, a current path between the at least one fifth terminal element and the third contact pad of the third semiconductor body, and a current path between the at least one fifth terminal element and the third contact pad of the fourth semiconductor body.

The disclosed subject matter may be better understood with reference to the following drawings and the description. The components in the figures are not necessarily to scale, emphasis instead being placed upon illustrating the principles of the disclosed subject matter. In the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 is a top view of a semiconductor module arrangement according to embodiments of the disclosure.

FIG. 3 is a top view of a semiconductor module arrangement according to further embodiments of the disclosure.

FIG. 4 is a top view of a semiconductor module arrangement according to even further embodiments of the disclosure.

FIG. 5 schematically illustrates current paths in a semiconductor arrangement according to embodiments of the disclosure.

FIG. 6 schematically illustrates current paths in a semiconductor arrangement according to further embodiments of the disclosure.

FIG. 7 schematically illustrates current paths in a semiconductor arrangement according to even further embodiments of the disclosure.

FIG. 8 schematically illustrates current paths in a semiconductor arrangement according to even further embodiments of the disclosure.

FIG. 9 is a top view of a semiconductor module arrangement according to further embodiments of the disclosure.

FIG. 10 is a top view of a semiconductor module arrangement according to even further embodiments of the disclosure.

### DETAILED DESCRIPTION

In the following detailed description, reference is made to the accompanying drawings. The drawings show specific examples in which the disclosed subject matter may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element, or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connecting pads and includes at least one semiconductor element with electrodes. The pads are electrically connected to the electrodes which includes that the pads are the electrodes and vice versa.

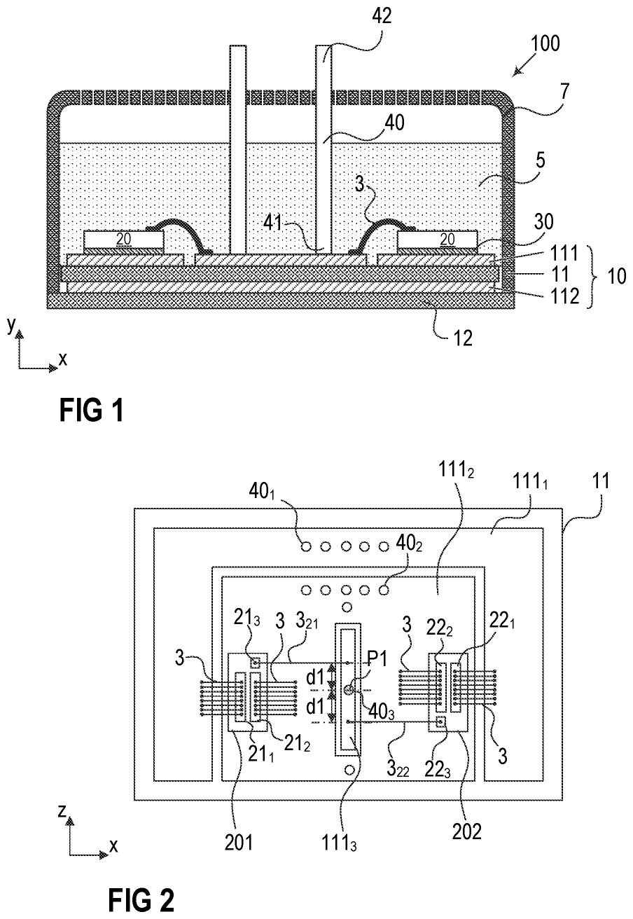

Referring to FIG. 1, a cross-sectional view of a power semiconductor module arrangement 100 is schematically illustrated. The power semiconductor module arrangement 100 includes a housing 7 and a substrate 10. The substrate 10 includes a dielectric insulation layer 11, a structured first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 12 which forms a ground surface of the housing 7, while the housing 7 itself solely comprises sidewalls and a cover. This, however, is only an example. It is also possible that the housing 7 further comprises a ground surface and the substrate 10 and the base plate 12 be arranged inside the housing 7. In some power semiconductor module arrangements 100, more than one substrate 10 is arranged on a single base plate 12 or on the ground surface of a housing 7. It is also possible that the substrate 10 itself forms a ground surface of the housing 7.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), and/or any other suitable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes three different sections. This, however, is only an example. Any other number of sections is possible. Different semiconductor bodies 20 may be mounted to the same or to different sections of the first metallization layer 111. Different sections of the first metallization layer 111 may have no electrical connection or may be electrically connected to one or more other sections using electrical connection elements 3 such as, e.g., bonding wires or bonding ribbons. Electrical connections 3 may also include connection plates, conductor rails, or connection clips, for example, to name just a few examples. The one or more semiconductor bodies 20 may be electrically and mechanically connected to the substrate 10 by an electrically conductive connection layer 30. Such an electrically conductive connection layer 30 may be a solder layer, a layer of an electrically conductive adhesive, or a layer of a sintered metal powder, e.g., a sintered silver powder, for example. According to other examples, it is also possible that the second metallization layer 112 is a structured layer. It is further possible to omit the second metallization layer 112 altogether. The substrate 10 may also be implemented as a multilayered substrate (not specifically illustrated) having more than one dielectric insulation layer 11 and at least one metallization layer arranged between two respective dielectric insulation layers, which may be referred to as “buried metallization layer”. For example, by providing an additional dielectric insulation layer between the second metallization layer 112 and the base plate 12, the second metallization layer 112 would become a buried metallization in this sense. The at least one buried metallization layer may also be structured, as described with respect to the first metallization layer 111. An electrical contact to the respective buried metallization layer (between different metallization layers of the multilayered substrate) may be established by one or more so-called “vias”, which are electrically conductive connections extending through a dielectric insulation layer arranged next to the respective buried metallization layer and to another metallization layer, which may be the first, second or a further buried metallization layer. The respective buried metallization layer, or at least a section of the buried metallization layer, may be used to transfer electric currents or signals. For example, the respective buried metallization layer may be used in a similar way as bonding wires to connect different nodes and/or circuit elements arranged on the substrate. In other words, connection elements 3 may also be formed by or may include a section of a buried metallization layer (a section of an additional metallization layer) of a multilayered substrate contacted by corresponding vias. Thus, a multilayered substrate may be used to replace some or all superficial connection elements, and/or it may be used to achieve a higher interconnection complexity between circuit nodes.

The power semiconductor module arrangement 100 illustrated in FIG. 1 further includes terminal elements 40. The terminal elements 40 are electrically connected to the first metallization layer 111 and provide an electrical connection between the inside and the outside of the housing 7. The terminal elements 40 may be electrically connected to the first metallization layer 111 with a first end 41, while a second end 42 of each of the terminal elements 40 protrudes out of the housing 7. The terminal elements 40 may be electrically contacted from the outside at their respective second ends 42. A first part of the terminal elements 40 may extend through the inside of the housing 7 in a vertical direction y. The vertical direction y is a direction perpendicular to a top surface of the substrate 10, wherein the top surface of the substrate 10 is a surface on which the at least one semiconductor body 20 is mounted. The terminal elements 40 illustrated in FIG. 1, however, are only examples. Terminal elements 40 may be implemented in any other way and may be arranged anywhere within the housing 7. For example, one or more terminal elements 40 may be arranged close to or adjacent to the sidewalls of the housing 7. Terminal elements 40 could also protrude through the sidewalls of the housing 7 instead of through the cover. The first end 41 of a terminal element 40 may be electrically and mechanically connected to the substrate 10 in any suitable way, e.g., by means of a welded joint or by means of an electrically conductive connection layer, for example (not explicitly illustrated in FIG. 1). Such an electrically conductive connection layer may be a solder layer, a layer of an electrically conductive adhesive, or a layer of a sintered metal powder, e.g., a sintered silver (Ag) powder, for example. The first end 41 of a terminal element 40 may also be electrically coupled to the substrate 10 via one or more electrical connections 3, for example.

The power semiconductor module arrangement 100 may further include an encapsulant 5. Encapsulant 5 may consist of or include a silicone gel or may be a rigid molding compound, for example. The encapsulant 5 may at least partly fill the interior of the housing 7, thereby covering the components and electrical connections that are arranged on the substrate 10. The terminal elements 40 may be partly embedded in the encapsulant 5. At least their second ends 42, however, are not covered by the encapsulant 5 and protrude from the encapsulant 5 through the housing 7 to the outside of the housing 7. The encapsulant 5 is configured to protect the components and electrical connections of the power semiconductor module 100, in particular the components arranged on the substrate 10 inside the housing 7, from certain environmental conditions and mechanical damage.

The layout of a semiconductor arrangement (e.g., semiconductor bodies 20, electrical connections 3, terminal elements 40, etc.) generally may be chosen to minimize the required size of the at least one substrate while, at the same time, also minimizing an unequal distribution of current densities, electrical losses, and thermal stress. Symmetry is often essential with respect to gate driving and parasitic inductances. Lateral semiconductor devices such as, e.g., GaN HEMTs, which have all contact pads (e.g., gate, source and drain contact pads) arranged on their top side and no contact pads on their bottom side, generally pose problems with regard to a symmetrical arrangement of the devices, especially for devices that are operated in parallel. A symmetrical arrangement of lateral devices often results in increased chip manufacturing costs, complex designs, and decreased flexibility in the production line.

In order to avoid the above mentioned drawbacks, a semiconductor module arrangement according to embodiments of the disclosure comprises a substrate 10 comprising a dielectric insulation layer 11 and a first metallization layer 111 arranged on a surface of the dielectric insulation layer 11. The first metallization layer 111 comprises a first section 111₁, a second section 111₂, and a third section 111₃. A first semiconductor body 201 and an identical second semiconductor body 202 are arranged on the first metallization layer 111, wherein each of the first semiconductor body 201 and the second semiconductor body 202 has a first contact pad 21₁, 22₁, a second contact pad 21₂, 22₂, and a third contact pad 21₃, 22₃ arranged on a top side of the respective semiconductor body 201, 202 that faces away from the substrate 10. That is, the first and second semiconductor body 201, 202 are lateral semiconductor devices. As the first semiconductor body 201 is identical to the second semiconductor body 202, the semiconductor bodies 201, 202 are of the same type (e.g., GaN HEMTs) and have identical switching and transmittance characteristics. Further, the contact pads 21₁, 22₁, 21₂, 22₂, 21₃, 22₃ are arranged identically on the top sides of the first and second semiconductor body 201, 202 (identical contact pad layout). In other words, the first semiconductor body 201 may be readily replaced by the identical second semiconductor body 202, and vice versa, without affecting the electrical properties and the function of the semiconductor module arrangement. The third contact pad 21₃ of the first semiconductor body 201 is electrically coupled to the third section 111₃ of the first metallization layer 111 by means of a first electrical connection element 3₂₁, and the third contact pad 22₃ of the second semiconductor body 202 is electrically coupled to the third section 111₃ of the first metallization layer 111 by means of a second electrical connection element 3₂₂. The semiconductor module arrangement further comprises at least one third terminal element 40₃ arranged on the third section 111₃. In this way, a control signal may be provided (e.g., from outside of a housing in which the semiconductor module arrangement may be arranged) to the third section 111₃ and from there, via the first electrical connection element 3₂₁ to the first semiconductor body 201, and via the second electrical connection element 3₂₂ to the second semiconductor body 202.

A first current path 8021 between the third contact pad 21₃ of the first semiconductor body 201 and the at least one third terminal element 40₃ (e.g., a third terminal element 40₃ of the at least one third terminal element 40₃ that is arranged closest to the first electrical connection element 3₂₁) provides identical voltage and current transfer characteristics as a second current path 80₂₂ between the third contact pad 22₃ of the second semiconductor body 202 and the at least one third terminal element 40₃ (e.g., a third terminal element 40₃ of the at least one third terminal element 40₃ that is arranged closest to the second electrical connection element 3₂₂). Each of the first and second electrical connection elements 3₂₁, 3₂₂ comprises one or more bonding wires, one or more bonding ribbons, a connection rail, or a section of an additional metallization layer of the substrate 10 that is contacted by corresponding vias. In this way, a control signal provided via the third terminal element 40₃ reaches the third contact pad 21₃ of the first semiconductor body 201 and the third contact pad 22₃ of the second semiconductor body 202 at the same time and with similar signal properties. That is, for example, that the third contact pads 21₃, 22₃ will have an essentially identical potential (or voltage) when a control signal is applied to the third terminal element 40₃. This allows to operate the first semiconductor body 201 and the second semiconductor body 202 in a highly symmetrical way. That is, the first semiconductor body 201 and the second semiconductor body 202 will switch on or off at essentially the same time. Further, the first semiconductor body 201 and the second semiconductor body 202 will have identical current and voltage transients during the switching operations as well as, for example, the same current densities during operation. To achieve this, the first current path 80₂₁ and the second current path 80₂₂ may exhibit at least one of essentially identical or identical ohmic behaviors, essentially identical or identical inductive behaviors, and essentially identical or identical capacitive behaviors, for example. (Essentially) identical ohmic behaviors, (essentially) identical inductive behaviors and (essentially) identical capacitive behaviors of the current paths 80₂₁, 80₂₂ generally result in an impedance difference of the two current paths 80₂₁, 80₂₂ that is significantly smaller than an (input) impedance difference of the first and second semiconductor bodies 201, 202. (Input) impedance differences of the first and second semiconductor bodies 201, 202 may result from typical production variations, for example. In other words, a sum of the impedances of the different elements of the first current path 80₂₁ may be (essentially) identical to a sum of the impedances of the different elements of the second current path 80₂₂. The term “identical” as used herein should be construed such that the related property of different entities such as, e.g., the ohmic behaviors of the first and second current paths 80₂₁, 80₂₂, are very similar. It may also be said that the different entities may be designed such that the related properties are exactly the same, but slight deviations may occur based on manufacturing tolerances. Manufacturing tolerances may vary between different applications and different manufacturing processes used to produce the different entities.

The third contact pads 21₃, 22₃ may form or may be coupled to a control electrode (e.g., gate electrode) of the first and second semiconductor body 201, 202, respectively. In particular, each of the first and second semiconductor body 201, 202 may comprise a control electrode and a controllable load path between a first load electrode and a second load electrode. The first contact pads 21₁, 22₁ may form or may be coupled to the respective first load electrode (e.g., drain electrode), and the second contact pads 21₂, 22₂ may form or may be coupled to the respective second load electrode (e.g., source electrode) of the first and second semiconductor body 201, 202, for example.

Now referring to FIG. 2, one exemplary embodiment of the disclosure is schematically illustrated. In this arrangement, a single (e.g., exactly one) third terminal element 40₃ is arranged on the third section 111₃. The single third terminal element 40₃ is arranged between a first connection point and a second connection point, wherein the first connection point is a point at which the first electrical connection element 3₂₁ is connected to the third section 111₃, and the second connection point is a point at which the second electrical connection element 3₂₂ is connected to the third section 111₃. In the example illustrated in FIG. 2, the third terminal element 40₃ is arranged centrally between the first connection point and the second connection point. In other words, a distance d1 between the third terminal element 40₃ and the first connection point equals a distance d1 between the third terminal element 40₃ and the second connection point. The third section 111₃ in this example is arranged between the first semiconductor body 201 and the second semiconductor body 202 in a horizontal direction x. The first semiconductor body 201 is arranged point symmetrical to the second semiconductor body 202 about a center of symmetry P1. The center of symmetry P1 in this example coincides with the position of the third terminal element 40₃. That is, the different elements of the semiconductor module arrangement of FIG. 2 are arranged in a highly (point) symmetrical way in order for the first current path and the second current path to be identical (i.e. to provide identical voltage and current transfer characteristics).

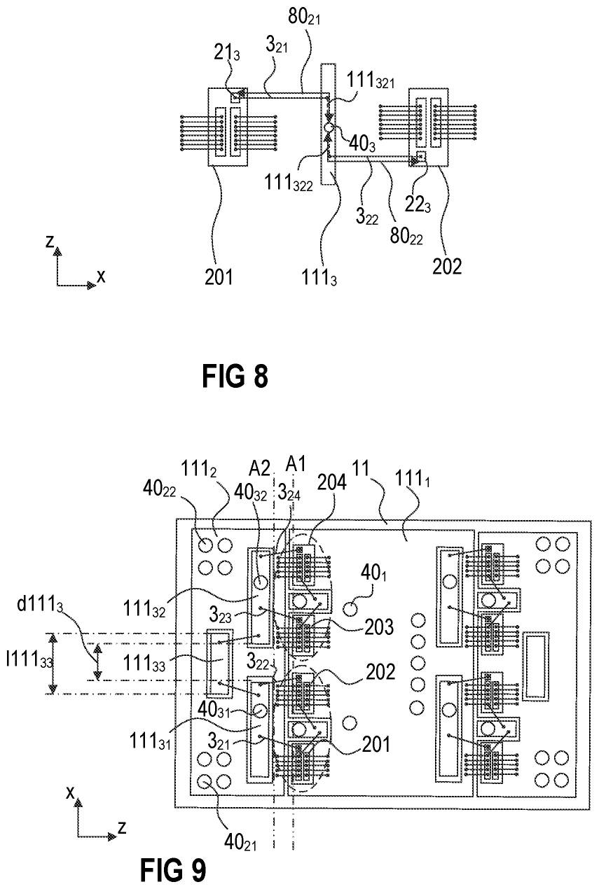

The first current path 80₂₁ is formed by the first electrical connection element 3₂₁ and a first segment 111₃₂₁ of the third section 111₃ arranged between the first connection point and the third terminal element 40₃, and the second current path 80₂₂ is formed by the second electrical connection element 3₂₂ and a second segment 111₃₂₂ of the third section 111₃ arranged between the second connection point and the third terminal element 40₃. This is schematically illustrated in further detail in FIG. 8, in which all features that are not necessary for the definition of the current paths are omitted for the sake of clarity. In this example, the dimensions and the material of the first electrical connection element 3₂₁ are identical to the dimensions and the material of the second electrical connection element 3₂₂, and a length of the first segment 111₃₂₁ of the third section 111₃ is identical to a length of the second segment 111₃₂₂ of the third section 111₃. That is, if the first electrical connection element 3₂₁ comprises, e.g., exactly one bonding wire comprising a first material and having a first diameter and a first length, the second electrical connection element 3₂₂ also comprises exactly one bonding wire comprising the same first material and having the same first diameter and first length.

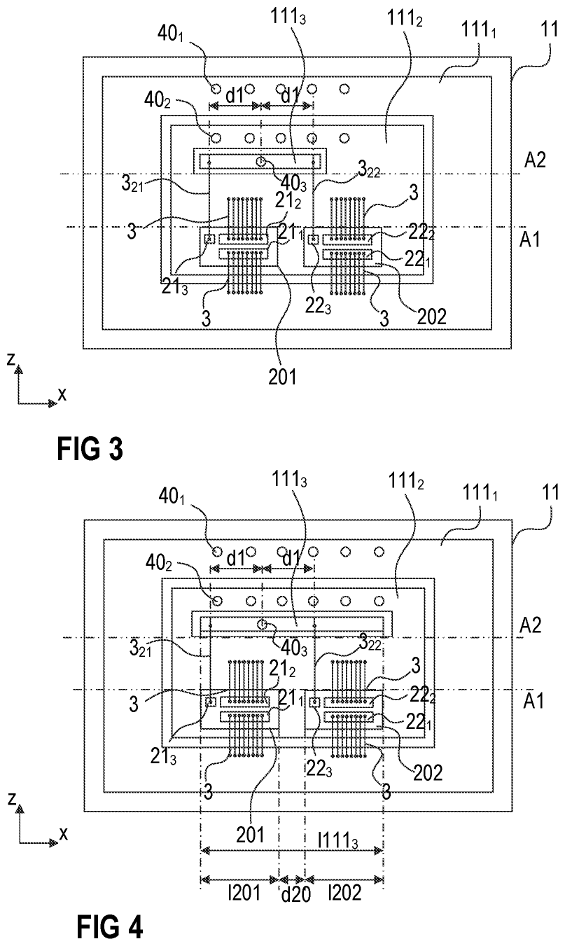

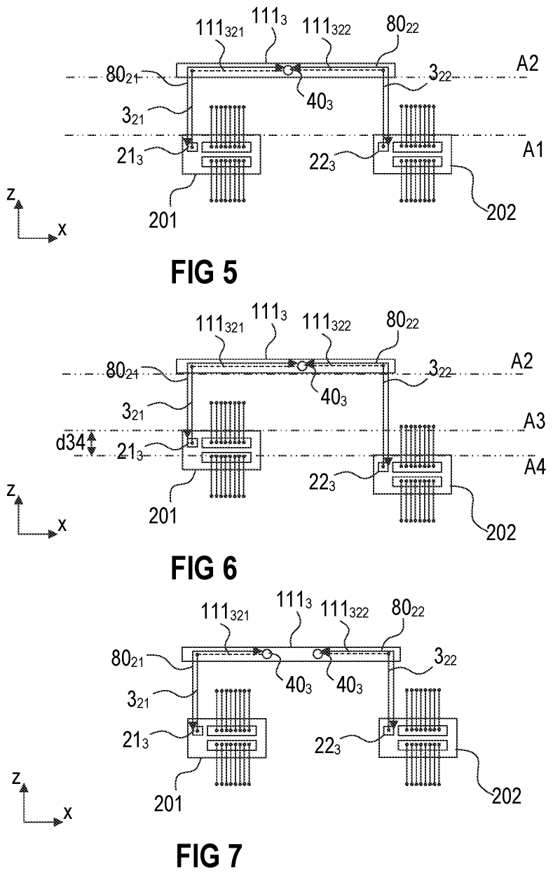

Arranging the first semiconductor body 201 and the second semiconductor body 202 point symmetrical about a center of symmetry P1, however, is only one example of how symmetrical driving of the semiconductor bodies 201, 202 can be achieved. Now referring to FIG. 3, it is also possible that the first semiconductor body 201 and the second semiconductor body 202 be arranged on the same side with respect to the third section 111₃ in a second horizontal direction z. In this case, as the first semiconductor body 201 and the second semiconductor body 202 are identical and, therefore, the contact pads 21₁, 22₁, 21₂, 22₂, 21₃, 22₃ are arranged identically on the top sides of the first and second semiconductor body 201, 202, an orientation of the first semiconductor body 201 corresponds to an orientation of the second semiconductor body 202. That is, the first semiconductor body 201 and the second semiconductor body 202 are not arranged symmetrically with respect to each other. In this way, the first current path 80₂₁ may provide identical voltage and current transfer characteristics as the second current path 80₂₂. Similar to what has been described above with respect to FIG. 2, the third terminal element 40₃ is arranged (centrally) between a first connection point and a second connection point, wherein the first connection point is a point at which the first electrical connection element 3₂₁ is connected to the third section 111₃, and the second connection point is a point at which the second electrical connection element 3₂₂ is connected to the third section 111₃. In other words, in the example illustrated in FIG. 3, a distance d1 between the third terminal element 40₃ and the first connection point equals a distance d1 between the third terminal element 40₃ and the second connection point. This is illustrated in further detail in FIG. 5, for example.

In the examples illustrated in FIGS. 2, 3, 5 and 8, for example, exactly one third terminal element 40₃ is arranged on the third section 111₃ and between the first connection point and the second connection point. In particular, the exactly one third terminal element 40₃ is arranged centrally between the first connection point and the second connection point. Such a symmetrical arrangement (point symmetric or axially symmetrical) of the connection points with respect to a single third terminal element 40₃, however, is only an example. As is schematically illustrated in FIG. 6, for example, it is also possible that a length of the first segment 111₃₂₁ of the third section 111₃ differs from a length of the second segment 111₃₂₂ of the third section 111₃. That is, the first segment 111₃₂₁, due to the different lengths, provides different voltage and current transfers as compared to the second segment 111₃₂₂. In order for the entire first current path 80₂₁ to provide identical voltage and current transfer characteristics as the second current path 80₂₂, the first electrical connection element 3₂₁ may also provide different voltage and current transfers as compared to the second electrical connection element 3₂₂. As is schematically illustrated in FIG. 6, for example, as the second segment 111₃₂₂ is shorter than the first segment 111₃₂₁, the second electrical connection element 3₂₂ may be longer than the first electrical connection element 3₂₁, in order to compensate for the different lengths of the first and second segment 111₃₂₁, 111₃₂₂. Instead of or in addition to providing electrical connection elements having different lengths 3₂₁, 3₂₂, it is also possible to provide electrical connection elements 3₂₁, 3₂₂ having different diameters and/or different materials, for example. In any case, however, a sum of the impedances of the different elements of the first current path 80₂₁ may be identical to a sum of the impedances of the different elements of the second current path 80₂₂.

In the example illustrated in FIG. 5, the third section 111₃ is an elongated section that is arranged along a second horizontal line A2. That is, a first side of the third section 111₃ which faces towards the first and second semiconductor bodies 201, 202 coincides with at least a section of the second horizontal line A2. The first semiconductor body 201 and the second semiconductor body 202 are arranged along a first horizontal line A1 which is parallel to the second horizontal line A2. A first side of the first semiconductor body 201 which faces the third section 111₃ and a first side of the second semiconductor body 202 which faces the third section 111₃ each coincide with a different section of the first horizontal line A1. That is, a distance between the first semiconductor body 201 and the third section 111₃ equals a distance between the second semiconductor body 202 and the third section 111₃, and further equals a distance between the first horizontal line A1 and the second horizontal line A2.

In contrast to this, in the example illustrated in FIG. 6, the first semiconductor body 201 is arranged along a third horizontal line A3 and the second semiconductor body 202 is arranged along a fourth horizontal line A4, wherein the third horizontal line A3 and the fourth horizontal line A4 are parallel to each other as well as to the second horizontal line A2. That is, a first side of the first semiconductor body 201 which faces the third section 111₃ coincides with a section of the third horizontal line A3, and a first side of the second semiconductor body 202 which faces the third section 111₃ coincides with a section of the fourth horizontal line A4. In other words, a distance between the first semiconductor body 201 and the third section 111₃ differs from a distance between the second semiconductor body 202 and the third section 111₃.

Now referring to FIG. 7, a similar arrangement as the arrangement of FIG. 5 is schematically illustrated. In the example illustrated in FIG. 7, however, two third terminal elements 40₃ are arranged on the third section 111₃ and between the first connection point and the second connection point. Identical control signals may be provided via the two third terminal elements 40₃. In this example, the first current path 80₂₁ is formed by the first electrical connection element 3₂₁ and a first segment 111₃₂₁ of the third section 111₃ arranged between the first connection point and the at least one third terminal element 40₃ (e.g., the third terminal element 40₃ of the at least one third terminal element 40₃ that is arranged closest to the first connection point). Similarly, the second current path 80₂₂ is formed by the second electrical connection element 3₂₂ and a second segment 111₃₂₂ of the third section 111₃ arranged between the second connection point and the at least one third terminal element 40₃ (e.g., the third terminal element 40₃ of the at least one third terminal element 40₃ that is arranged closest to the second connection point). In the example illustrated in FIG. 7, a length of the first segment 111₃₂₁ equals a length of the second segment 111₃₂₂, similar to what has been described with respect to FIG. 5 above. That is, the first current path 80₂₁ is symmetrical to the second current path 80₂₂. It is, however, also possible that the length of the first segment 111₃₂₁ differs from the length of the second segment 111₃₂₂, similar to what has been described with respect to FIG. 6 above, irrespective of how many third terminal elements 40₃ are arranged on the third section 111₃. That is, the first current path 80₂₁ may not be symmetrical to the second current path 80₂₂, while still providing identical voltage and current transfer characteristics.

It is generally also possible that more than two third terminal elements 40₃ are arranged on the third section 111₃ and between the first connection point and the second connection point. Irrespective of the number of third terminal elements 40₃ arranged on the third section 111₃, the first current path 80₂₁ is formed by the first electrical connection element 3₂₁ and a first segment 111₃₂₁ of the third section 111₃ arranged between the first connection point and the at least one third terminal element 40₃ (e.g., the third terminal element 40₃ of the at least one third terminal element 40₃ that is arranged closest to the first connection point), and the second current path 80₂₂ is formed by the second electrical connection element 3₂₂ and a second segment 111₃₂₂ of the third section 111₃ arranged between the second connection point and the at least one third terminal element 40₃ (e.g., the third terminal element 40₃ of the at least one third terminal element 40₃ that is arranged closest to the second connection point). It is even possible, if two or more third terminal elements 40₃ are arranged on the third section 111₃, that one or more of the two or more third terminal elements 40₃ are not arranged between the first connection point and the second connection point.

What has been described with respect to FIGS. 5, 6 and 7 above for a first semiconductor body 201 and a second semiconductor body 202 arranged on the same side of the third section 111₃ similarly applies for a point symmetrical arrangement in which the first semiconductor body 201 and the second semiconductor body 202 are arranged on different sides of the third section 111₃ (e.g., FIGS. 2 and 8).

In all examples, the third section 111₃ and the at least one third terminal element 40₃ arranged thereon may be arranged distant from the first semiconductor body 201 and the second semiconductor body 202 in the second horizontal direction z. Further, in all examples, the first contact pad 21₁ of the first semiconductor body 201 and the first contact pad 22₁ of the second semiconductor body 202 may be electrically coupled to the first section 111₁ of the first metallization layer 111, and the second contact pad 21₂ of the first semiconductor body 201 and the second contact pad 22₂ of the second semiconductor body 202 may be electrically coupled to the second section 111₂ of the first metallization layer 111. According to one example, the second contact pad 21₂ of the first semiconductor body 201 and the second contact pad 22₂ of the second semiconductor body 202 may be source pads, and the first contact pad 21₁ of the first semiconductor body 201 and the first contact pad 22₁ of the second semiconductor body 202 may be drain pads. Each of the first contact pad 21₁ of the first semiconductor body 201 and the first contact pad 22₁ of the second semiconductor body 202 may be electrically coupled to the first section 111₁ of the first metallization layer 111 by means of an electrical connection element 3, and each of the second contact pad 21₂ of the first semiconductor body 201 and the second contact pad 22₂ of the second semiconductor body 202 may be electrically coupled to the second section 111₂ of the first metallization layer 111 by means of an electrical connection element 3. Each of the electrical connection elements 3 may comprise one or more bonding wires, one or more bonding ribbons, a connection rail, or a section of an additional metallization layer of the substrate 10 that is contacted by corresponding vias, for example. The first semiconductor body 201 and the second semiconductor body 202 may be arranged on the second section 111₂ of the first metallization layer 111. That is, the first semiconductor body 201 and the second semiconductor body 202 may be arranged on that section of the first metallization layer to which their respective second contact pads 21₂, 22₂ are electrically coupled (e.g., semiconductor bodies arranged on source potential).

The second section 111₂ of the first metallization layer 111 may horizontally surround the third section 111₃, as is schematically illustrated in FIGS. 2 and 3, for example. The semiconductor module arrangement may further comprise one or more second terminal elements 40₂ arranged on the second section 111₂ of the first metallization layer 111, in order to electrically contact the second contact pads 21₂, 22₂ of the first and second semiconductor bodies 201, 202. The third section 111₃, in the second horizontal direction z, may be arranged between the one or more second terminal elements 40₂ and the first and second semiconductor bodies 201, 202. In this way, any (load) currents flowing between the second contact pads 21₂, 22₂ and the second terminal elements 40₂ have to flow around the third section 111₃. In this way, a higher symmetry of the (load) currents can be achieved, for example. A direct current flow between the second terminal elements 40₂ and the semiconductor bodies 201, 202 is avoided. The currents provided by means of the second terminal elements 40₂ are forced to split symmetrically to flow around the island formed by the third section 111₃.

In the semiconductor module arrangement as schematically illustrated in FIG. 3, the third section 111₃ has a minimum length in the first horizontal direction x. That is, the third section 111₃ has a length in the first horizontal direction x that is just marginally longer than the sum of the length of the first segment 111₃₂₁ of the third section 111₃ and the length of the second segment 111₃₂₂ of the third section 111₃. This minimum length is generally sufficient to achieve gate driving symmetry, as has been discussed above.

Now referring to FIG. 4, it is however also possible that the third section 111₃ has a length that is significantly larger than the minimum length. As has been discussed above, the semiconductor module arrangement may comprise one or more second terminal elements 40₂ arranged on the second section 111₂ of the first metallization layer 111, and the third section 111₃, in the second horizontal direction z, may be arranged between the one or more second terminal elements 40₂ and the first and second semiconductor bodies 201, 202. The third section 111₃ in the arrangement of FIG. 4 has a length l111₃ in the first horizontal direction x, wherein the length l111₃ of the third section 111₃ is equal to or greater than the sum of a length l201 of the first semiconductor body 201, a length l202 of the second semiconductor body 202, and a distance d20 between the first semiconductor body 201 and the second semiconductor body 202 in the first horizontal direction x. The third section 111₃ may further be aligned with the first semiconductor body 201 and the second semiconductor body 202 in the first horizontal direction x, for example. In this way, the distance a (load) current has to flow between the second terminal elements 40₂ and the second contact pad 22₂ of the second semiconductor body 202 is increased as compared to the semiconductor arrangement of FIG. 3, where the third section 111₃ only has the minimum length. That is, the arrangement of FIG. 4, in contrast to the arrangement of FIG. 3, in addition to providing a gate driving symmetry, is also more symmetric with regard to the load currents. The third terminal element 40₃ in the arrangement of FIG. 4, however, remains in its position (centrally) between the first connection point and the second connection point. That is, the position of the third terminal element 40₃ on the third section 111₃ may remain unaffected by the extension of the length of the third section 111₃ in the first horizontal direction x. The third terminal element 40₃ may be arranged (centrally) between the first connection point and the second connection point but is not necessarily arranged centrally on the third section 111₃. A distance between the third terminal element 40₃ and a first end of the third section 111₃ may be smaller or larger than a distance between the third terminal element 40₃ and a second end of the third section 111₃ opposite the first end in the first horizontal direction x.

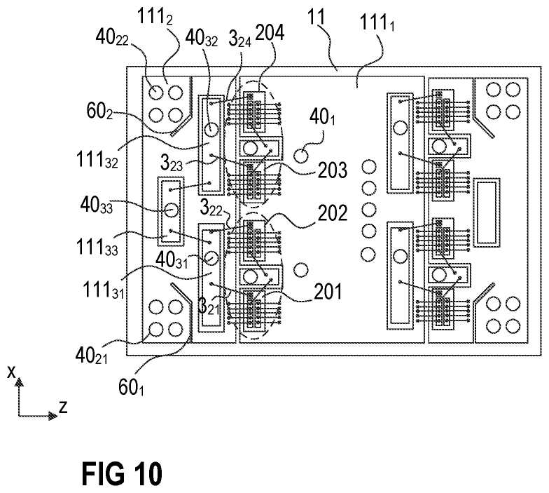

The semiconductor module arrangements according to the different embodiments of the disclosure that have been exemplarily discussed above provide gate driving symmetry and, optionally, symmetry of load currents for lateral semiconductor devices. The semiconductor module arrangements as discussed above may be used as sub-structures in more complex topologies, at least the arrangements as exemplarily discussed with respect to FIGS. 3, 5, 6 and 7, which will be described in more detail in the following with respect to FIGS. 9 and 10. Each sub-structure provides two parallel driven semiconductors. More complex topologies in which two or more sub-structures may be used include, but are not limited to, half-bridge topologies or 3-level topologies such as, e.g., neutral point clamped (NPC) or active neutral point clamped topologies. For example, in a more complex topology, two or more sub-structures may be operated in parallel.

Now referring to FIG. 9, the semiconductor module arrangement may comprise two essentially identical sub-structures. That is, in addition to a first sub-structure, the semiconductor module arrangement may further comprise an identical second sub-structure. The semiconductor module arrangement therefore may further comprise a fourth section 111₃₂ of the first metallization layer 111, and a third semiconductor body 203 and an identical fourth semiconductor body 204 arranged on the first metallization layer 111. Each of the third semiconductor body 203 and the fourth semiconductor body 204 has a first contact pad, a second contact pad, and a third contact pad arranged on a top side of the respective semiconductor body 203, 204, wherein the top side is a side that faces away from the substrate 10. An orientation of the third semiconductor body 203 and the fourth semiconductor body 204 corresponds to an orientation of the first and the second semiconductor body 201, 202. The third semiconductor body 203 and the fourth semiconductor body 204 are arranged on the same side with respect to the third section 11131 and the fourth section 111₃₂ as the first semiconductor body 201 and the second semiconductor body 202. The third contact pad of the third semiconductor body 203 is electrically coupled to the fourth section 111₃₂ of the first metallization layer 111 by means of a third electrical connection element 3₂₃, and the third contact pad of the fourth semiconductor body 204 is electrically coupled to the fourth section 111₃₂ of the first metallization layer 111 by means of a fourth electrical connection element 3₂₄.

The semiconductor module arrangement further comprises at least one fourth terminal element 40₃₂ arranged on the fourth section 111₃₂. The number of fourth terminal elements 40₃₂ may correspond to the number of third terminal elements 40₃₁ in order for the two sub-systems to be symmetrical to each other (with respect to the current paths). A third current path between the third contact pad of the third semiconductor body 203 and the at least one fourth terminal element 40₃₂ (e.g., a fourth terminal element 40₃₂ of the at least one fourth terminal element 40₃₂ that is arranged closest to the third electrical connection element 3₂₃) provides identical voltage and current transfer characteristics as a fourth current path between the third contact pad of the fourth semiconductor body 204 and the at least one fourth terminal element 40₃₂ (a fourth terminal element 40₃₂ of the at least one fourth terminal element 40₃₂ that is arranged closest to the fourth electrical connection element 3₂₄). Similar to what has been discussed above with respect to the first sub-structure, each of the third and fourth electrical connection elements 3₂₃, 3₂₄ comprises one or more bonding wires, one or more bonding ribbons, a connection rail, or a section of an additional metallization layer of the substrate 10 that is contacted by corresponding vias, for example.

The second sub-structure, similar to the first sub-structure, provides gate driving symmetry and, optionally symmetry of load currents. It is also possible that the first sub-structure and second sub-structure provide identical voltage and current transfer characteristics. That is, the first current path 80₂₁ may provide identical voltage and current transfer characteristics not only as the second current path 80₂₂, but also as the third current path and the fourth current path.

The first contact pad of the third semiconductor body 203 and the first contact pad of the fourth semiconductor body 204 may be electrically coupled to the first section 111₁ of the first metallization layer 111, and the second contact pad of the third semiconductor body 203 and the second contact pad of the fourth semiconductor body 204 may be electrically coupled to the second section 111₂ of the first metallization layer 111. That is, the first and second contact pads of the third and fourth semiconductor bodies 203, 204 may be electrically coupled to the same sections of the first metallization layer as the first and second contact pads 21₁, 22₁, 21₂, 22₂ of the first and second semiconductor bodies 201, 202, respectively. The second section 111₂ of the first metallization layer 111 may horizontally surround both of the third section 111₃₁ and the fourth section 111₃₂. The third section 111₃₁ and the fourth section 111₃₂ may both be elongated sections that are arranged along the same second horizontal line A2. The first, second, third, and fourth semiconductor bodies 201, 202, 203, 204 may be arranged along the same first horizontal line A1, as is schematically illustrated in FIG. 9. It is also possible that two identical sub-structures similar to the sub-structures as described with respect to FIGS. 6 and 7, for example, are included in a more complex topology.

The semiconductor module arrangement may optionally further comprise a fifth section 111₃₃ of the first metallization layer 111, wherein the second section 111₂ of the first metallization layer 111 also horizontally surrounds the fifth section 111₃₃. The third section 111₃₁, in the second horizontal direction z, is arranged between the fifth section 111₃₃ and the first semiconductor body 201 and the second semiconductor body 202, and, similarly, the fourth section 111₃₂, in the second horizontal direction z, is arranged between the fifth section 111₃₃ and the third semiconductor body 203 and the fourth semiconductor body 204. A length l111₃₃ of the fifth section 111₃₃ in the first horizontal direction x may be equal to or greater than a distance d111₃ between the third section 111₃₁ and the fourth section 111₃₂ in the first horizontal direction x. In this way, similar to what has been described with respect to the length l111₃ of the third section 111₃ with reference to FIG. 4 above, load current symmetry may be achieved in the semiconductor module arrangement.

The fifth section 111₃₃ may have the sole function of guiding currents along defined paths to achieve load current symmetry. That is, the fifth section 111₃₃ may not be electrically connected to any other section or any element of the semiconductor module arrangement (not specifically illustrated). It is, however, also possible that the fifth section 111₃₃ is electrically coupled to the third section 111₃₁ by means of an electrical connection element 3, and that the fifth section 111₃₃ is further electrically coupled to the fourth section 111₃₂ by means of an electrical connection element 3, as is schematically illustrated in FIG. 9. Each of the electrical connection elements 3 may comprise one or more bonding wires, one or more bonding ribbons, a connection rail, or a section of an additional metallization layer of the substrate 10 that is contacted by corresponding vias, for example. In the arrangement as illustrated in FIG. 9, however, no terminal element is arranged on the fifth section 111₃₃ of the first metallization layer 111. The fifth section 111₃₃ in this example is used to provide a low-inductive and low-ohmic connection of the signals provided via the one or more third terminal elements 40₃₁ and the one or more fourth terminal elements 40₃₂. Such a connection can be useful in compensating asymmetries in external (gate) driving circuits if both sub-systems are operated by means of the same gate driver, for example. The fifth section 111₃₃ may not be electrically connected to any other section or any element of the semiconductor module arrangement if the sub-systems are operated in an interleaved manner, for example.

According to another example, the semiconductor module arrangement may further comprise at least one fifth terminal element 40₃₃ arranged on the fifth section 111₃₃ of the first metallization layer 111, as is exemplarily illustrated in FIG. 10. In this case, a fifth current path between the at least one fifth terminal element 40₃₃ (e.g., a fifth terminal element 40₃₃ of the at least one fifth terminal element 40₃₃ that is arranged closest to a connection point between the electrical connection element 3 and the fifth section 111₃₃) and the at least one fourth terminal element 40₃₂ (e.g., a fourth terminal element 40₃₂ of the at least one fourth terminal element 40₃₂ that is arranged closest to a connection point between the electrical connection element 3 and the fourth section 111₃₂) provides identical voltage and current transfer characteristics as a sixth current path between the at least one fifth terminal element 40₃₃ (a fifth terminal element 40₃₃ of the at least one fifth terminal element 40₃₃ that is arranged closest to a connection point between the electrical connection element 3 and the fifth section 111₃₃) and the at least one third terminal element 40₃₁ (e.g., a third terminal element 40₃₁ of the at least one third terminal element 40₃₁ that is arranged closest to a connection point between the electrical connection element 3 and the third section 111₃₁).

As has been described above, the semiconductor module arrangement may comprise a plurality of second terminal elements 40₂ arranged on the second section 111₂ of the first metallization layer 111. According to one example and as is schematically illustrated in FIGS. 9 and 10, the plurality of second terminal elements 40₂ may comprise a first group of second terminal elements 40₂₁ and a second group of second terminal elements 40₂₂ arranged on the second section 111₂ of the first metallization layer 111. The third section 111₃₁, in the second horizontal direction z, may be arranged between the first group of second terminal elements 40₂₁ and the first semiconductor body 201 and the second semiconductor body 202, and the fourth section 111₃₂, in the second horizontal direction z, may be arranged between the second group of second terminal elements 40₂₂ and the third semiconductor body 203 and the fourth semiconductor body 204. This further increases the load current symmetry in the semiconductor module arrangement, as the distances the currents have to flow between each of the first, second, third, and fourth semiconductor bodies 201, 202, 203, 204 and the closest ones of the plurality of second terminal elements 40₂₂ are essentially identical.

Now referring to FIG. 10, the load current symmetry may be increased even further. As is schematically illustrated in FIG. 10, the semiconductor module arrangement may further comprise a first trench 60₁ extending through the second section 111₂ of the first metallization layer 111 and between the first group of second terminal elements 40₂₁ and the first semiconductor body 201 and the second semiconductor body 202, and a second trench 60₂ extending through the second section 111₂ of the first metallization layer 111 and between the second group of second terminal elements 40₂₂ and the third semiconductor body 203 and the fourth semiconductor body 204. The flow of currents flowing between the second terminal elements 40₂ and the semiconductor bodies 201, 202, 203, 204 may be precisely controlled by means of such trenches 60₁, 60₂ as well as by appropriately choosing a length of the third, fourth and fifth sections 111₃₁, 111₃₂, 111₃₃ of the first metallization layer 111.

In the example illustrated in FIG. 9, terminal elements 40₃₁, 40₃₂ are arranged on each of the third section 111₃₁ and the fourth section 111₃₂, but not on the fifth section 111₃₃. In the example illustrated in FIG. 10, terminal elements 40₃₁, 40₃₂, 40₃₃ are arranged on each of the third section 111₃₁, the fourth section 111₃₂, and the fifth section 111₃₃. It is, however, also possible (not specifically illustrated) that terminal elements 40₃₃ are arranged on the fifth section 111₃₃, but not on the third section 111₃₁ and the fourth section 111₃₂. That is, an alternative semiconductor module arrangement may comprise a substrate 10 comprising a dielectric insulation layer 11 and a first metallization layer 111 arranged on a surface of the dielectric insulation layer 11, wherein the first metallization layer 111 comprises a first section 111₁, a second section 111₂, a third section 111₃₁, a fourth section 111₃₂, and a fifth section 111₃₃, wherein the second section 111₂ horizontally surrounds each of the third section 111₃₁, the fourth section 111₃₂, and the fifth section 111₃₃.

The semiconductor module arrangement may further comprise identical first, second, third, and fourth semiconductor bodies 201, 202, 203, 204 arranged on the first metallization layer 111, wherein each of the first semiconductor body 201, the second semiconductor body 202, the third semiconductor body 203, and the fourth semiconductor body 204 has a first contact pad 21₁, 22₁, a second contact pad 21₂, 22₂, and a third contact pad 21₃, 22₃ arranged on a top side of the respective semiconductor body 201, 202, 203, 204 that faces away from the substrate 10. The third contact pad 21₃ of the first semiconductor body 201 is electrically coupled to the third section 111₃₁ of the first metallization layer 111 by means of a first electrical connection element 3₂₁, the third contact pad 22₃ of the second semiconductor body 202 is electrically coupled to the third section 111₃, 111₃₁ of the first metallization layer 111 by means of a second electrical connection element 3₂₂, the third contact pad of the third semiconductor body 203 is electrically coupled to the fourth section 111₃₂ of the first metallization layer 111 by means of a third electrical connection element 3₂₃, and the third contact pad of the fourth semiconductor body 204 is electrically coupled to the fourth section 111₃₂ of the first metallization layer 111 by means of a fourth electrical connection element 3₂₄. The fifth section 111₃₃ is electrically coupled to the third section 111₃₁ by means of an electrical connection element 3, and the fifth section 111₃₃ is electrically coupled to the fourth section 111₃₂ by means of an electrical connection element 3. Each of the electrical connection elements 3, 3₂₁, 3₂₂, 3₂₃, 3₂₄ comprises one or more bonding wires, one or more bonding ribbons, a connection rail, or a section of an additional metallization layer of the substrate 10 that is contacted by corresponding vias.

The power semiconductor module arrangement further comprises at least one fifth terminal element 40₃₃ arranged on the fifth section 111₃₃ of the first metallization layer 111. A current path between the at least one fifth terminal element 40₃₃ (e.g., a fifth terminal element 40₃₃ of the at least one fifth terminal element 40₃₃ that is arranged closest to a connection point between the respective electrical connection element 3 and the fifth section 111₃₃) and the third contact pad 21₃ of the first semiconductor body 201 provides identical voltage and current transfer characteristics as each of a current path between the at least one fifth terminal element 40₃₃ (e.g., a fifth terminal element 40₃₃ of the at least one fifth terminal element 40₃₃ that is arranged closest to a connection point between the respective electrical connection element 3 and the fifth section 111₃₃) and the third contact pad 22₃ of the second semiconductor body 202, a current path between the at least one fifth terminal element 40₃₃ (e.g., a fifth terminal element 40₃₃ of the at least one fifth terminal element 40₃₃ that is arranged closest to a connection point between the respective electrical connection element 3 and the fifth section 111₃₃) and the third contact pad of the third semiconductor body 203, and a current path between the at least one fifth terminal element 40₃₃ (e.g., a fifth terminal element 40₃₃ of the at least one fifth terminal element 40₃₃ that is arranged closest to a connection point between the respective electrical connection element 3 and the fifth section 111₃₃) and the third contact pad of the fourth semiconductor body 204.

As is schematically illustrated in FIGS. 9 and 10, a more complex arrangement may even comprise more than two-sub structures (visible on the right hand sides of FIGS. 9 and 10). Any further sub-structures, however, are optional and can also be omitted.

### Examples

In some examples, a semiconductor module arrangement comprises a substrate (10) comprising a dielectric insulation layer (11) and a first metallization layer (111) arranged on a surface of the dielectric insulation layer (11), wherein the first metallization layer (111) comprises a first section (1111), a second section (1112), and a third section (1113, 11131). The semiconductor module arrangement further comprises a first semiconductor body (201) and an identical second semiconductor body (202) arranged on the first metallization layer (111), wherein each of the first semiconductor body (201) and the second semiconductor body (202) has a first contact pad (211, 221), a second contact pad (212, 222), and a third contact pad (213, 223) arranged on a top side of the respective semiconductor body (201, 202) that faces away from the substrate (10), wherein the third contact pad (213) of the first semiconductor body (201) is electrically coupled to the third section (1113, 11131) of the first metallization layer (111) by means of a first electrical connection element (321), the third contact pad (223) of the second semiconductor body (202) is electrically coupled to the third section (1113, 11131) of the first metallization layer (111) by means of a second electrical connection element (322). The semiconductor module arrangement further comprises at least one third terminal element (403, 4031) arranged on the third section (1113, 11131), a first current path (8021) between the third contact pad (213) of the first semiconductor body (201) and the at least one third terminal element (403, 4031) provides identical voltage and current transfer characteristics as a second current path (8022) between the third contact pad (223) of the second semiconductor body (202) and the at least one third terminal element (403, 4031), and each of the first and second electrical connection elements (321, 322) comprises one or more bonding wires, one or more bonding ribbons, a connection rail, or a section of an additional metallization layer of the substrate (10) that is contacted by corresponding vias.

In some examples of the semiconductor module arrangement, the first current path (8021) and the second current path (8022) exhibit at least one of identical ohmic behaviors, identical inductive behaviors, and identical capacitive behaviors.

In some examples of the semiconductor module arrangement, the first current path (8021) is formed by the first electrical connection element (321) and a first segment (111321) of the third section (1113, 11131) arranged between a first connection point and the at least one third terminal element (403, 4031), wherein the first connection point is a point at which the first electrical connection element (321) is connected to the third section (1113, 11131), and the second current path (8022) is formed by the second electrical connection element (322) and a second segment (111322) of the third section (1113, 11131) arranged between a second connection point and the at least one third terminal element (403, 4031), wherein the second connection point is a point at which the second electrical connection element (322) is connected to the third section (1113, 11131).

In some examples of the semiconductor module arrangement, the first contact pad (211) of the first semiconductor body (201) and the first contact pad (221) of the second semiconductor body (202) are electrically coupled to the first section (1111) of the first metallization layer (111), and the second contact pad (212) of the first semiconductor body (201) and the second contact pad (222) of the second semiconductor body (202) are electrically coupled to the second section (1112) of the first metallization layer (111).

In some examples of the semiconductor module arrangement, the third section (1113, 11131) is arranged between the first semiconductor body (201) and the second semiconductor body (202).

In some examples of the semiconductor module arrangement, the first semiconductor body (201) is arranged point symmetrical to the second semiconductor body (202) about a center of symmetry (P1).

In some examples of the semiconductor module arrangement, comprising exactly one third terminal element (403) arranged at the center of symmetry (P1), wherein the dimensions and the material of the first electrical connection element (321) are identical to the dimensions and the material of the second electrical connection element (322), and a length of the first segment (111321) of the third section (1113, 11131) is identical to a length of the second segment (111322) of the third section (1113, 11131).

In some examples of the semiconductor module arrangement, the first semiconductor body (201) and the second semiconductor body (202) are arranged on the same side with respect to the third section (1113, 11131) in a second horizontal direction (z).

In some examples of the semiconductor module arrangement, an orientation of the first semiconductor body (201) corresponds to an orientation of the second semiconductor body (202).

In some examples of the semiconductor module arrangement, the third section (1113, 11131) of the first metallization layer (111) and the at least one third terminal element (403, 4031) arranged thereon are arranged distant from the first semiconductor body (201) and the second semiconductor body (202) in the second horizontal direction (z).

In some examples of the semiconductor module arrangement, the third section (1113, 11131) has a length (l1113) in a first horizontal direction (x) perpendicular to the second horizontal direction (z), and the length (l1113) of the third section (1113, 11131) is equal to or greater than the sum of a length (l201) of the first semiconductor body (201), a length (l202) of the second semiconductor body (202), and a distance (d20) between the first semiconductor body (201) and the second semiconductor body (202) in the first horizontal direction (x).

In some examples of the semiconductor module arrangement, the first semiconductor body (201) and the second semiconductor body (202) are arranged on the second section (1112) of the first metallization layer (111).

In some examples of the semiconductor module arrangement, each of the first contact pad (211) of the first semiconductor body (201) and the first contact pad (221) of the second semiconductor body (202) is electrically coupled to the first section (1111) of the first metallization layer (111) by means of an electrical connection element (3), each of the second contact pad (212) of the first semiconductor body (201) and the second contact pad (222) of the second semiconductor body (202) is electrically coupled to the second section (1112) of the first metallization layer (111) by means of an electrical connection element (3), and each of the electrical connection elements (3) comprises one or more bonding wires, one or more bonding ribbons, a connection rail, or a section of an additional metallization layer of the substrate (10) that is contacted by corresponding vias.

In some examples of the semiconductor module arrangement, the second section (1112) of the first metallization layer (111) horizontally surrounds the third section (1113, 11131).

In some examples of the semiconductor module arrangement, the semiconductor module arrangement further comprises one or more second terminal elements (402) arranged on the second section (1112) of the first metallization layer (111), wherein the third section (1113, 11131), in the second horizontal direction (z), is arranged between the one or more second terminal elements (402) and the first and second semiconductor bodies (201, 202).

In some examples of the semiconductor module arrangement, the semiconductor module arrangement further comprises a fourth section (11132) of the first metallization layer (111), and a third semiconductor body (203) and an identical fourth semiconductor body (204) arranged on the first metallization layer (111), wherein each of the third semiconductor body (203) and the fourth semiconductor body (204) has a first contact pad, a second contact pad, and a third contact pad arranged on a top side of the respective semiconductor body (203, 204), wherein the top side is a side that faces away from the substrate (10), wherein an orientation of the third semiconductor body (203) and the fourth semiconductor body (204) corresponds to an orientation of the first and the second semiconductor body (201, 202), the third semiconductor body (203) and the fourth semiconductor body (204) are arranged on the same side with respect to the third section (11131) and the fourth section (11132) as the first semiconductor body (201) and the second semiconductor body (202), the third contact pad of the third semiconductor body (203) is electrically coupled to the fourth section (11132) of the first metallization layer (111) by means of a third electrical connection element (323), the third contact pad of the fourth semiconductor body (204) is electrically coupled to the fourth section (11132) of the first metallization layer (111) by means of a fourth electrical connection element (324), the semiconductor module arrangement further comprises at least one fourth terminal element (4032) arranged on the fourth section (11132), a third current path between the third contact pad of the third semiconductor body (203) and the at least one fourth terminal element (4032) provides identical voltage and current transfer characteristics as a fourth current path between the third contact pad of the fourth semiconductor body (204) and the at least one fourth terminal element (4032), and each of the third and fourth electrical connection elements (323, 324) comprises one or more bonding wires, one or more bonding ribbons, a connection rail, or a section of an additional metallization layer of the substrate (10) that is contacted by corresponding vias.

In some examples of the semiconductor module arrangement, the first contact pad of the third semiconductor body (203) and the first contact pad of the fourth semiconductor body (204) are electrically coupled to the first section (1111) of the first metallization layer (111), and the second contact pad of the third semiconductor body (203) and the second contact pad of the fourth semiconductor body (204) are electrically coupled to the second section (1112) of the first metallization layer (111).

In some examples of the semiconductor module arrangement, the second section (1112) of the first metallization layer (111) horizontally surrounds the fourth section (11132).

In some examples of the semiconductor module arrangement, the semiconductor module arrangement further comprises a fifth section (11133) of the first metallization layer (111), wherein the second section (1112) of the first metallization layer (111) horizontally surrounds the fifth section (11133), the third section (11131), in the second horizontal direction (z), is arranged between the fifth section (11133) and the first semiconductor body (201) and the second semiconductor body (202), and the fourth section (11132), in the second horizontal direction (z), is arranged between the fifth section (11133) and the third semiconductor body (203) and the fourth semiconductor body (204).

In some examples of the semiconductor module arrangement, a length (l11133) of the fifth section (11133) in the first horizontal direction (x) is equal to or greater than a distance (d1113) between the third section (11131) and the fourth section (11132) in the first horizontal direction (x).

In some examples of the semiconductor module arrangement, the fifth section (11133) is electrically coupled to the third section (11131) by means of an electrical connection element (3), and the fifth section (11133) is electrically coupled to the fourth section (11132) by means of an electrical connection element (3), wherein each of the electrical connection elements (3) comprises one or more bonding wires, one or more bonding ribbons, a connection rail, or a section of an additional metallization layer of the substrate (10) that is contacted by corresponding vias.

In some examples of the semiconductor module arrangement, the semiconductor module arrangement further comprises at least one fifth terminal element (4033) arranged on the fifth section (11133) of the first metallization layer (111), wherein a fifth current path between the at least one fifth terminal element (4033) and the at least one fourth terminal element (4032) provides identical voltage and current transfer characteristics as a sixth current path between the at least one fifth terminal element (4033) and the at least one third terminal element (4031).

In some examples of the semiconductor module arrangement, the semiconductor module arrangement further comprises a first group of second terminal elements (4021) and a second group of second terminal elements (4022) arranged on the second section (1112) of the first metallization layer (111), wherein the third section (11131), in the second horizontal direction (z), is arranged between the first group of second terminal elements (4021) and the first semiconductor body (201) and the second semiconductor body (202), and the fourth section (11132), in the second horizontal direction (z), is arranged between the second group of second terminal elements (4022) and the third semiconductor body (203) and the fourth semiconductor body (204).

In some examples of the semiconductor module arrangement, the semiconductor module arrangement further comprises a first trench (601) extending through the second section (1112) of the first metallization layer (111) and between the first group of second terminal elements (4021) and the first semiconductor body (201) and the second semiconductor body (202), and a second trench (602) extending through the second section (1112) of the first metallization layer (111) and between the second group of second terminal elements (4022) and the third semiconductor body (203) and the fourth semiconductor body (204).

In some examples, a semiconductor module arrangement comprises: a substrate (10) comprising a dielectric insulation layer (11) and a first metallization layer (111) arranged on a surface of the dielectric insulation layer (11), wherein the first metallization layer (111) comprises a first section (1111), a second section (1112), a third section (1113, 11131), a fourth section (11132), and a fifth section (11133), wherein the second section (1112) horizontally surrounds each of the third section (1113, 11131), the fourth section (11132), and the fifth section (11133). The semiconductor module arrangement further comprises identical first, second, third, and fourth semiconductor bodies (201, 202, 203, 204) arranged on the first metallization layer (111), wherein each of the first semiconductor body (201), the second semiconductor body (202), the third semiconductor body (203), and the fourth semiconductor body (204) has a first contact pad (211, 221), a second contact pad (212, 222), and a third contact pad (213, 223) arranged on a top side of the respective semiconductor body (201, 202, 203, 204) that faces away from the substrate (10), wherein the third contact pad (213) of the first semiconductor body (201) is electrically coupled to the third section (1113, 11131) of the first metallization layer (111) by means of a first electrical connection element (321), the third contact pad (223) of the second semiconductor body (202) is electrically coupled to the third section (1113, 11131) of the first metallization layer (111) by means of a second electrical connection element (322), the third contact pad of the third semiconductor body (203) is electrically coupled to the fourth section (11132) of the first metallization layer (111) by means of a third electrical connection element (323), the third contact pad of the fourth semiconductor body (204) is electrically coupled to the fourth section (11132) of the first metallization layer (111) by means of a fourth electrical connection element (324), the fifth section (11133) is electrically coupled to the third section (11131) by means of an electrical connection element (3), the fifth section (11133) is electrically coupled to the fourth section (11132) by means of an electrical connection element (3), each of the electrical connection elements (3, 321, 322, 323, 324) comprises one or more bonding wires, one or more bonding ribbons, a connection rail, or a section of an additional metallization layer of the substrate (10) that is contacted by corresponding vias. The power semiconductor module arrangement further comprises at least one fifth terminal element (4033) arranged on the fifth section (11133) of the first metallization layer (111), and a current path between the at least one fifth terminal element (4033) and the third contact pad (213) of the first semiconductor body (201) provides identical voltage and current transfer characteristics as each of a current path between the at least one fifth terminal element (4033) and the third contact pad (223) of the second semiconductor body (202), a current path between the at least one fifth terminal element (4033) and the third contact pad of the third semiconductor body (203), and a current path between the at least one fifth terminal element (4033) and the third contact pad of the fourth semiconductor body (204).

1. A semiconductor module arrangement comprising:
a substrate comprising a dielectric insulation layer and a first metallization layer arranged on a surface of the dielectric insulation layer, wherein the first metallization layer comprises a first section, a second section, and a third section; and
a first semiconductor body and a second semiconductor body arranged on the first metallization layer, wherein each of the first semiconductor body and the second semiconductor body has a first contact pad, a second contact pad, and a third contact pad arranged on a top side of the respective semiconductor body that faces away from the substrate, wherein
the third contact pad of the first semiconductor body is electrically coupled to the third section of the first metallization layer by means of a first electrical connection element,
the third contact pad of the second semiconductor body is electrically coupled to the third section of the first metallization layer by means of a second electrical connection element,
the semiconductor module arrangement comprises at least one third terminal element arranged on the third section,
a first current path between the third contact pad of the first semiconductor body and the at least one third terminal element provides identical voltage and current transfer characteristics as a second current path between the third contact pad of the second semiconductor body and the at least one third terminal element, and
each of the first electrical connection element and the second electrical connection element comprises at least one of one or more bonding wires, one or more bonding ribbons, a connection rail, or a section of an additional metallization layer of the substrate that is contacted by one or more corresponding vias.

2. The semiconductor module arrangement of claim 1, wherein the first current path and the second current path exhibit at least one of identical ohmic behaviors, identical inductive behaviors, or identical capacitive behaviors.

3. The semiconductor module arrangement of claim 1, wherein
the first current path is formed by the first electrical connection element and a first segment of the third section arranged between a first connection point and the at least one third terminal element, wherein the first connection point is a point at which the first electrical connection element is connected to the third section, and
the second current path is formed by the second electrical connection element and a second segment of the third section arranged between a second connection point and the at least one third terminal element, wherein the second connection point is a point at which the second electrical connection element is connected to the third section.

4. The semiconductor module arrangement of claim 1, wherein
the first contact pad of the first semiconductor body and the first contact pad of the second semiconductor body are electrically coupled to the first section of the first metallization layer, and
the second contact pad of the first semiconductor body and the second contact pad of the second semiconductor body are electrically coupled to the second section of the first metallization layer.

5. The semiconductor module arrangement of claim 1, wherein the third section is arranged between the first semiconductor body and the second semiconductor body.

6. The semiconductor module arrangement of claim 5, wherein the first semiconductor body is arranged point symmetrical to the second semiconductor body about a center of symmetry.

7. The semiconductor module arrangement of claim 6, comprising one third terminal element arranged at the center of symmetry, wherein one or more dimensions and one or more materials of the first electrical connection element are identical to one or more dimensions and one or more materials of the second electrical connection element, and a length of the first segment of the third section is identical to a length of the second segment of the third section.

8. The semiconductor module arrangement of claim 1, wherein the first semiconductor body and the second semiconductor body are arranged on the same side with respect to the third section in a second horizontal direction.

9. The semiconductor module arrangement of claim 8, wherein an orientation of the first semiconductor body corresponds to an orientation of the second semiconductor body.

10. The semiconductor module arrangement of claim 8, wherein the third section of the first metallization layer and the at least one third terminal element arranged thereon are arranged distant from the first semiconductor body and the second semiconductor body in the second horizontal direction.

11. The semiconductor module arrangement of claim 10, wherein the third section has a length in a first horizontal direction perpendicular to the second horizontal direction, wherein the length of the third section is equal to or greater than the sum of a length of the first semiconductor body, a length of the second semiconductor body, and a distance between the first semiconductor body and the second semiconductor body in the first horizontal direction.

12. The semiconductor module arrangement of claim 8, wherein the first semiconductor body and the second semiconductor body are arranged on the second section of the first metallization layer.

13. The semiconductor module arrangement of claim 8, wherein
each of the first contact pad of the first semiconductor body and the first contact pad of the second semiconductor body is electrically coupled to the first section of the first metallization layer by means of an electrical connection element,
each of the second contact pad of the first semiconductor body and the second contact pad of the second semiconductor body is electrically coupled to the second section of the first metallization layer by means of an electrical connection element, and
each of the electrical connection elements comprises at least one of one or more bonding wires, one or more bonding ribbons, a connection rail, or a section of an additional metallization layer of the substrate that is contacted by one or more corresponding vias.

14. The semiconductor module arrangement of claim 8, wherein the second section of the first metallization layer horizontally surrounds the third section.

15. The semiconductor module arrangement of claim 8, comprising one or more second terminal elements arranged on the second section of the first metallization layer, wherein the third section, in the second horizontal direction, is arranged between the one or more second terminal elements and the first and second semiconductor bodies.

16. The semiconductor module arrangement of claim 8, comprising
a fourth section of the first metallization layer, and
a third semiconductor body and a fourth semiconductor body arranged on the first metallization layer, wherein each of the third semiconductor body and the fourth semiconductor body has a first contact pad, a second contact pad, and a third contact pad arranged on a top side of the respective semiconductor body, wherein the top side is a side that faces away from the substrate, wherein
an orientation of the third semiconductor body and the fourth semiconductor body corresponds to an orientation of the first and the second semiconductor body,
the third semiconductor body and the fourth semiconductor body are arranged on the same side with respect to the third section and the fourth section as the first semiconductor body and the second semiconductor body,
the third contact pad of the third semiconductor body is electrically coupled to the fourth section of the first metallization layer by means of a third electrical connection element,
the third contact pad of the fourth semiconductor body is electrically coupled to the fourth section of the first metallization layer by means of a fourth electrical connection element,
the semiconductor module arrangement comprises at least one fourth terminal element arranged on the fourth section,
a third current path between the third contact pad of the third semiconductor body and the at least one fourth terminal element provides identical voltage and current transfer characteristics as a fourth current path between the third contact pad of the fourth semiconductor body and the at least one fourth terminal element, and
each of the third electrical connection element and the fourth electrical connection element comprises at least one of one or more bonding wires, one or more bonding ribbons, a connection rail, or a section of an additional metallization layer of the substrate that is contacted by one or more corresponding vias.

17. The semiconductor module arrangement of claim 16, wherein
the first contact pad of the third semiconductor body and the first contact pad of the fourth semiconductor body are electrically coupled to the first section of the first metallization layer, and
the second contact pad of the third semiconductor body and the second contact pad of the fourth semiconductor body are electrically coupled to the second section of the first metallization layer.

18. The semiconductor module arrangement of claim 16, wherein the second section of the first metallization layer horizontally surrounds the fourth section.

19. The semiconductor module arrangement of claim 16, comprising a fifth section of the first metallization layer, wherein
the second section of the first metallization layer horizontally surrounds the fifth section,
the third section, in the second horizontal direction, is arranged between the fifth section and the first semiconductor body and the second semiconductor body, and
the fourth section, in the second horizontal direction, is arranged between the fifth section and the third semiconductor body and the fourth semiconductor body.

20. A semiconductor module arrangement comprising:
a substrate comprising a dielectric insulation layer and a first metallization layer arranged on a surface of the dielectric insulation layer, wherein the first metallization layer comprises a first section, a second section, a third section, a fourth section, and a fifth section, wherein the second section horizontally surrounds each of the third section, the fourth section, and the fifth section; and
a first semiconductor body, a second semiconductor body, a third semiconductor body, and a fourth semiconductor body arranged on the first metallization layer, wherein each of the first semiconductor body, the second semiconductor body, the third semiconductor body, and the fourth semiconductor body has a first contact pad, a second contact pad, and a third contact pad arranged on a top side of the respective semiconductor body that faces away from the substrate, wherein
the third contact pad of the first semiconductor body is electrically coupled to the third section of the first metallization layer by means of a first electrical connection element,
the third contact pad of the second semiconductor body is electrically coupled to the third section of the first metallization layer by means of a second electrical connection element,
the third contact pad of the third semiconductor body is electrically coupled to the fourth section of the first metallization layer by means of a third electrical connection element,
the third contact pad of the fourth semiconductor body is electrically coupled to the fourth section of the first metallization layer by means of a fourth electrical connection element,
the fifth section is electrically coupled to the third section by means of an electrical connection element,
the fifth section is electrically coupled to the fourth section by means of an electrical connection element,
each of the electrical connection elements comprises at least one of one or more bonding wires, one or more bonding ribbons, a connection rail, or a section of an additional metallization layer of the substrate that is contacted by one or more corresponding vias,
the power semiconductor module arrangement comprises at least one fifth terminal element arranged on the fifth section of the first metallization layer, and
a current path between the at least one fifth terminal element and the third contact pad of the first semiconductor body provides identical voltage and current transfer characteristics as each of a current path between the at least one fifth terminal element and the third contact pad of the second semiconductor body, a current path between the at least one fifth terminal element and the third contact pad of the third semiconductor body, and a current path between the at least one fifth terminal element and the third contact pad of the fourth semiconductor body.
